(19) United States
(12) Patent Application Publication
(10) Pub. No.: US 2007/0222009 A1
(43) Pub. Date: Sep. 27, 2007

(54) Integrated Pedestal Mount for MEMS Structure

(75) Inventor: Terje Kvisteroy, Horten (NO)

Correspondence Address: EDELL, SHAPIRO & FINNAN, LLC, 1901 RESEARCH BOULEVARD, SUITE 400, ROCKVILLE, MD, 20850, US

(73) Assignee: INFINEON TECHNOLOGIES SENSONOR AS, Horten (NO)

(21) Appl. No.: 11/684,175

(22) Filed: Mar. 9, 2007

(30) Foreign Application Priority Data
Mar. 24, 2006 (EP) 06111686.9

(51) Int. Cl. H01L 29/84

(52) U.S. Cl. 257/415

(57) ABSTRACT

A substrate is provided for supporting a MEMS device. The substrate includes a housing with an integral pedestal mount for supporting the MEMS device. The substrate can be combined with a MEMS device to form a sensor.

### CROSS REFERENCE TO RELATED APPLICATIONS

This application claims priority under 35 U.S.C. §119 to Application No. EP 06111686.9 filed on Mar. 24, 2006, entitled “Integrated Pedestal Mount for MEMS Structure,” the entire contents of which are hereby incorporated by reference.

### FIELD OF THE INVENTION

The present invention relates to packaging for a sensor and more particularly an integrated pedestal mount for a micro-electro-mechanical system (MEMS) structure.

### BACKGROUND

MEMS structures are widely used in such varied technological fields as the automobile industry, biomedical applications, and the electronics industry. MEMS structures are used as sensors of various types. Examples of MEMS structures include but are not limited to: MEMS gyroscopes that can be used by the automobile industry to detect yaw; MEMS accelerometers which can be used to deploy airbags in automobiles; and MEMS pressure sensors which, appropriately manufactured can be used to measure car tire pressure or even blood pressure.

MEMS structures typically include a mechanical structure that is fabricated onto a silicon substrate using micro-machining techniques.

As a result of their high surface area to volume ratio, MEMS structures are very sensitive to environmental parameters that may be connected to their intended function. In particular, they are very sensitive to thermal and mechanical stresses that may ultimately result in their failure and which can result in inaccuracy of their output.

It is therefore desirable to isolate the MEMS structure from its surrounding in order to minimize adverse effects, e.g., warping of the sensor, which adversely affects its performance.

It has been suggested to provide a soft material layer between a sensor and its respective supporting substrate. Furthermore, two layers of this soft material can be provided with an interstitial mounting plate. These additional layers require precise control of the quantity of adhesive used as well as precise control of the placement of the sensor.

Furthermore, a sensor isolation system is known that consists of a compliant interposer that is disposed between the package and the sensor in order to avoid thermal and mechanical stresses affecting the performance of the sensor. The compliant interposer comprises members that absorb the stresses that are present in the package in order to avoid their transference to the sensor. The provision of a compliant interposer that is not soldered in place, but rather is provided using an interference fit, overcomes the problem of precisely controlling the solder used in the connection between the sensor and the package.

A further development of this principle provides an alternative solution to the problems associated with solder and epoxy bonding by providing pillars on two co-operating substrates so that the two pieces slot together using an interference fit and provide an enclosed space in which the sensor is housed.

All of the above-mentioned approaches to reducing the stresses to which a sensor is exposed rely on precise machining of multiple co-operating parts. These parts, whether they take the form of soft layers of material with interstitial mounting plates; compliant interposers or co-operating substrates all add to the complexity of the manufacture of such devices.

In today's highly competitive electronics market it is crucial to be able to produce high quality products both reliably and economically. As a device becomes more complex, the manufacturing requirements also become more complex and therefore increasing the number of component parts required can increase the cost of production of the article. Furthermore, as many products are miniaturized the manufacturing tolerances on each of the parts must improve in line with the reduction in the overall size of the product in order to maintain consistency of manufacture. Moreover, the use of more parts imposes a critical challenge on matching the thermal properties of all parts involved.

### SUMMARY

A substrate for supporting a MEMS device includes a housing with an integral pedestal mount for supporting a MEMS devices, wherein the pedestal mount comprises an inlet hole formed therein.

By mounting the MEMS device directly onto the pedestal part of the substrate, the resulting sensor is more robust. In particular, it is possible for the sensor to retain its rigidity and stability over a wide range of temperature, vibrational stress and g-loading.

By reducing the number of parts and thereby the number of different materials involved, the sensor described herein is also more reliable over time as a result of the low hysteresis effects that result from the integral construction of the substrate and pedestal.

The substrate of the described device can be utilized with any standard MEMS structure, although has particular benefits for pressure sensing devices.

The pedestal mount is preferably elongate and provided with a smaller diameter than the cross section of the MEMS device, e.g., a base or top surface of the MEMS device. The housing may be ceramic or polymer based.

A sensor may be formed using the substrate and a MEMS device. The sensor may further comprise wire bonds for outputting signals from the sensor.

Furthermore, a method of manufacturing a sensor is described herein, the method comprising: forming the substrate using a multi-layering technique or molding technique; and bonding, e.g., die bonding, the MEMS device directly to the pedestal mount. The die bonding may be direct bonding or adhesive bonding.

The described method can use either a ceramic multi-layer technique or a polymer molding technique to provide the exact topology of the substrate as required. This results in a reduction in post-fabrication modifications that can introduce additional stresses to the substrate. The ceramic multi-layer technique and polymer molding technique are well-established methods of low cost 3D manufacturing technologies.

The above and still further features and advantages of the invention will become apparent upon consideration of the following definitions, descriptions and descriptive figures of specific embodiments thereof, wherein like reference numerals in the various figures are utilized to designate like components. While these descriptions go into specific details of device and methods, it should be understood that variations may and do exist and would be apparent to those skilled in the art based on the descriptions herein.

### BRIEF DESCRIPTION OF THE DRAWINGS

The integrated pedestal mount for MEMS structures will now be described with reference to the accompanying drawings, where:

FIG. 1 shows a cross section of a first example of a sensor according to the described device; and

FIG. 2 shows a cross section of a second example of a sensor according to the described device.

### DETAILED DESCRIPTION

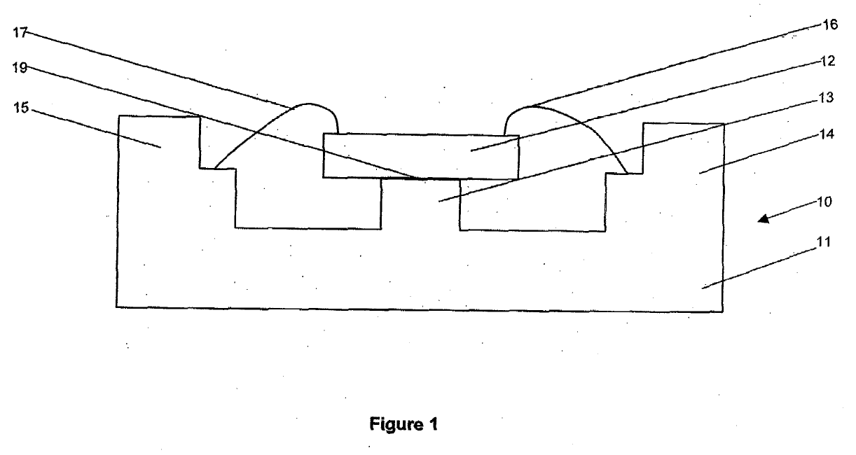

FIG. 1 shows a sensor 10 that comprises a substrate 11 and a MEMS structure 12. The substrate 11 is formed from a ceramic material or a polymer material. A ceramic material can be tailored to provide a close match for the coefficient of thermal expansion to either Si or glass and ceramics are known to maintain their material characteristics over time and thermal cycling resulting in a very stable material. An example of ceramic material may be Aluminium Nitride (AlN). Polymer materials are preferable for low cost applications due to the extremely low cost molding techniques. Examples of polymers are injection molded glass-fiber, reinforced nylon or PPS, or Liquid Crystal Polymer (LCP).

The substrate 11 is provided with an integral pedestal 13 onto which the MEMS structure 12 is bonded using adhesive 19. The pedestal 13 is elongate and preferably has a circular cross section. Although one of ordinary skill in the art would appreciate that any shape of cross section could be used, he would also appreciate that a circular cross section minimizes the stresses by reducing the number of sharp corners. The pedestal 13 has a constant cross sectional area or can be tapered having the smallest cross section closest to the MEMS die. Depending on the die bonding technique the surface of the pedestal may be metallized.

The substrate 11 is further provided with protective portions 14, 15 that extend beyond the MEMS structure 12. These portions 14, 15 provide an enclosed environment for the MEMS structure 12. In addition, the portion 14, 15 are used for attaching wire bonds 16, 17 which also attach to the MEMS structure 12.

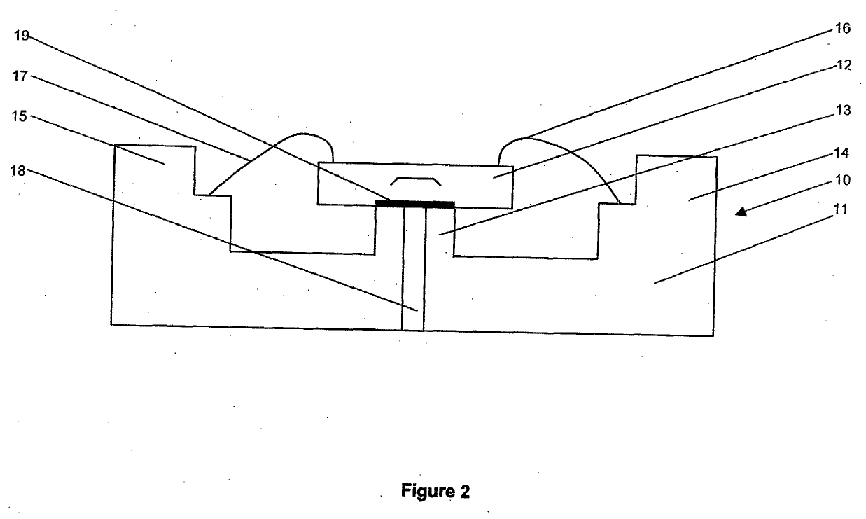

In addition to the features described above in connection with FIG. 1, the sensor 10 of FIG. 2 is provided with an inlet hole 18. This sensor 10 is suitable for use as a pressure sensor with the inlet hole 18 allowing the fluid to be measured to impinge on the sensor 10.

The sensors 10 shown in FIGS. 1 and 2 are compatible with any standard MEMS structure 12 and no specific adaptation of the MEMS structure 12 is required before it can be used in the sensor 10 when using an adhesive for the die bonding process. For direct bonding, metallizing or oxidizing the reverse side of the MEMS die may be necessary depending on the die bonding process parameters. For MEMS dies containing glass substrate or glass layer direct bonding can be performed directly.

The sensors 10 shown in FIGS. 1 and 2 are manufactured as follows. First, the substrate 12 is formed using a multi-layer technique for ceramic material or molding technique for polymer material. The MEMS structure is then bonded to the pedestal 13 using either direct bonding, e.g., anodic or metal bonding. Alternatively, the bonding may be adhesive using solder or an organic substance, e.g., epoxy.

While devices and methods have been described in detail with reference to specific embodiments thereof, it will be apparent to one of ordinary skill in the art that various changes and modifications can be made therein without departing from the spirit and scope of the invention. Accordingly, it is intended that the present methods and devices cover the modifications and variations of this method and device provided they come within the scope of the appended claims and their equivalents.

What is claimed is:

1. A substrate for supporting a micro-electro-mechanical system (MEMS) device, the substrate comprising:
a housing including an integral pedestal mount for supporting the MEMS device, the pedestal mount including an inlet hole formed therein.

2. The substrate according to claim 1, wherein the pedestal mount is elongate.

3. The substrate according to claim 1, wherein the pedestal mount has a smaller diameter than a cross section of the MEMS device.

4. The substrate according to claim 1, wherein the housing comprises a ceramic.

5. The substrate according to claim 1, wherein the housing comprises a polymer.

6. A sensor, comprising:
the substrate according to claim 1; and
the MEMS device.

7. The sensor according to claim 6, wherein the pedestal mount is elongate.

8. The sensor according to claim 6, wherein the pedestal mount has a smaller diameter than a cross section of the MEMS device.

9. The sensor according to claim 6, wherein the housing comprises a ceramic or a polymer.

10. The sensor according to claim 6, further comprising wire bonds for outputting signals from the sensor.

11. The sensor according to claim 6, wherein the MEMS device comprises a pressure sensor.

12. A method of manufacturing a sensor, comprising:
forming a substrate for supporting a micro-electro-mechanical system (MEMS) device, such that the substrate comprises a housing with an integral pedestal mount for supporting the MEMS device, the pedestal mount including an inlet hole formed therein; and
bonding the MEMS device directly to the pedestal mount.

13. The method according to claim 12, wherein the substrate is formed via a multi-layering technique or molding technique.

14. The method according to claim 12, wherein the substrate is formed such that the pedestal mount is elongate.

15. The method according to claim 12, wherein the substrate is formed such that the pedestal mount has a smaller diameter than a cross section of the MEMS device.

16. The method according to claim 12, wherein the housing is formed of ceramic or a polymer.

17. The method according to claim 12, wherein the sensor is formed to include bonding wire bonds for outputting signals from the sensor.

18. The method according to claim 12, wherein the sensor is formed as a pressure sensor.

19. The method according to claim 12, wherein bonding the MEMS device to the pedestal mount comprises direct bonding.

20. The method according to claim 12, wherein bonding the MEMS device to the pedestal mount comprises adhesive bonding.
